(19) United States
(12) Patent Application Publication
(10) Pub. No.: US 2012/0194974 A1
(43) Pub. Date: Aug. 2, 2012

(54) ENHANCED CHEMICAL STRENGTHENING GLASS FOR PORTABLE ELECTRONIC DEVICES

(75) Inventors: Douglas Weber, Arcadia, CA (US); Christopher Prest, San Francisco, CA (US); Stephen Paul Zadesky, Portola Valley, CA (US)

(73) Assignee: Apple Inc.

(21) Appl. No.: 13/121,385

(22) PCT Filed: Feb. 2, 2011
(86) PCT No.: PCT/US11/23499

§ 371 Date: Mar. 28, 2011

(51) Int. Cl. H05K 5/00; B32B 17/00; C03C 17/00; C03C 21/00

(52) U.S. Cl. 361/679.01; 65/30.1; 428/410

(57) ABSTRACT

Apparatus, systems and methods for improving strength of a thin glass member for an electronic device are disclosed. In one embodiment, the glass member can have improved strength characteristics in accordance with a predetermined stress profile. The predetermined stress profile can be formed through multiple stages of chemical strengthening. The stages can, for example, have a first ion exchange stage where larger ions are exchanged into the glass member, and a second ion exchange stage where some of the larger ions are exchanged out from the glass member. In one embodiment, the glass member can pertain to a glass cover for a housing for an electronic device. The glass cover can be provided over or integrated with a display.

### CROSS-REFERENCE TO OTHER APPLICATIONS

This application is a U.S. National-Stage entry under 35 U.S.C. §371 based on PCT International Application No. PCT/US2011/023499, filed Feb. 2, 2011 and entitled “ENHANCED CHEMICAL STRENGTHENING GLASS OF COVERS FOR PORTABLE ELECTRONIC DEVICES,” which is hereby incorporated herein by reference, which claims priority to: (i) U.S. Provisional Patent Application No. 61/300,793, filed Feb. 2, 2010 and entitled “TECHNIQUES FOR STRENGTHENING GLASS COVERS FOR PORTABLE ELECTRONIC DEVICES,” which is hereby incorporated herein by reference; and (ii) U.S. Provisional Patent Application No. 61/300,792, filed Feb. 2, 2010 and entitled “TECHNIQUES FOR STRENGTHENING GLASS COVERS FOR PORTABLE ELECTRONIC DEVICES,” which is hereby incorporated herein by reference.

### BACKGROUND OF THE INVENTION

Conventionally, small form factor devices, such as handheld electronic devices, have a display arrangement that includes various layers. The various layers usually include at least a display technology layer, and may additionally include a sensing arrangement and/or a cover window disposed over the display technology layer. By way of example, the display technology layer may include or pertain to a Liquid Crystal Display (LCD) that includes a Liquid Crystal Module (LCM). The LCM generally includes an upper glass sheet and a lower glass sheet that sandwich a liquid crystal layer therebetween. The sensing arrangement may be a touch sensing arrangement such as those used to create a touch screen. For example, a capacitive sensing touch screen can include substantially transparent sensing points or nodes dispersed about a sheet of glass (or plastic). In addition, the cover window, which is typically designed as the outer protective barrier of the layer stack.

The cover window, or glass cover, for a small form factor device can be made of plastic or glass. Plastic is durable but susceptible to being scratched. Glass is scratch resistant, but brittle. In general, the thicker the glass, the stronger it is. Unfortunately, however, the glass cover is often relatively thin, and may be a relatively weak component of the device structure especially at its edges. For example, the glass cover may be susceptible to damage when the portable electronic device is stressed in an abusive manner. Chemically strengthening has been used to strengthen glass. While this has generally worked well, there is a continuing need to provide ways to strengthen the glass covers.

### SUMMARY

Embodiments pertain to apparatus, systems and methods for improving strength of a thin glass member for an electronic device. In one embodiment, the glass member can have improved strength characteristics in accordance with a predetermined stress profile. The predetermined stress profile can be formed through multiple stages of chemical strengthening. The stages can, for example, have a first ion exchange stage where larger ions are exchanged into the glass member, and a second ion exchange stage where some of the larger ions are exchanged out from the glass member. In one embodiment, the glass member can pertain to a glass cover for a housing for an electronic device. The glass cover can be provided over or integrated with a display.

The invention can be implemented in numerous ways, including as a method, system, device, or apparatus. Several embodiments of the invention are discussed below.

As a method for producing a glass cover for an exposed surface of a consumer electronic product, one embodiment can, for example, include at least the acts of: obtaining a glass sheet; singulating the glass sheet into a plurality of glass covers, each of the glass covers being suitably sized to be provided on the exposed surface of a consumer electronic product; chemically strengthening the glass covers; and chemically toughening the glass covers.

As a consumer electronic product, one embodiment can, for example, include at least: a housing having a front surface, a back surface and side surfaces; electrical components provided at least partially internal to the housing, the electrical components including at least a controller, a memory, and a display, the display being provided at or adjacent the front surface of the housing; and a glass cover provided at or over the front surface of the housing such that it is provided over the display, wherein the glass cover is a chemically strengthened and chemically toughened glass cover.

As a cover glass member suitable for attachment to a housing for a handheld electronic device, the cover glass member being produced, strengthened and toughened by the process that in one embodiment can, for example, includes at least: obtaining a glass sheet; singulating the glass sheet into a plurality of glass cover members, each of the glass cover members being suitably sized to be provided on an exposed surface of the handheld electronic device, each of the glass cover members including edges and at least one non-edge portion; chemically strengthening at least the edges of each of the glass cover members, wherein chemically strengthening at least the edges of each of the glass cover members includes altering a composition of at least the edges such that the composition of at least the edges differs from a composition of the at least one non-edge portion; and toughening the glass cover members by reducing compressive stress in the edges of the glass cover members.

As a consumer electronic product, one embodiment can, for example, include at least: a housing having a front surface, a back surface and side surfaces; electrical components provided at least partially internal to the housing; and a glass member that has been chemically strengthened such that a peak compressive stress for the glass member is sub-surface of an exposed surface of the glass member.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like structural elements, and in which:

FIG. 1A is a perspective diagram of glass member in accordance with one embodiment.

FIG. 1B is a simplified diagram of electronic device in accordance with one embodiment.

FIG. 2 is a flow diagram of glass cover process according to one embodiment.

FIGS. 3A-3E are cross-sectional diagrams of glass covers for electronic device housings according to various embodiments.

FIG. 4A is a cross-sectional diagram of a glass cover for an electronic device housings according to an additional embodiment that pertains to a chamfered edge geometry.

FIG. 4B illustrates a cross-sectional diagram of glass cover having reference edge geometry that includes a straight corner (i.e., sharp corner).

FIGS. 5A and 5B are diagrammatic representations of electronic device according to one embodiment.

FIGS. 6A and 6B are diagrammatic representations of electronic device according to another embodiment of the invention.

FIG. 7A is a diagram of a partial cross-sectional view of a glass cover, which shows an initial tension/compression stress profile according to one embodiment.

FIG. 7B is a diagram of a partial cross-sectional view of a glass cover, which shows a reduced tension/compression stress profile according to one embodiment.

FIG. 7C is a diagram of compressive surface stress versus compressive surface layer depth, which shows a triangular continuum of intersecting ranges for reduced central tension, reduced compressive surface stress and compressive surface layer depth for the glass cover.

FIG. 8A illustrates a process of chemically treating surfaces of a glass piece in accordance with one embodiment.

FIG. 8B is another flow diagram which illustrates a process of strengthening and toughening glass covers according to one embodiment.

FIG. 8C illustrates an exemplary profile according to one embodiment.

FIGS. 9A and 9B are cross-sectional diagrams of a glass cover which has been chemically treated such that a chemically strengthened layer is created according to one embodiment.

FIG. 10A is a diagrammatic representation of a chemical treatment process that involves submerging a glass cover in an ion bath according to one embodiment.

FIG. 10B is a diagrammatic representation of a chemical treatment process that involves submerging a glass cover in a sodium bath after the glass cover has previously been submerged in a Alkali metal bath according to one embodiment.

### DETAILED DESCRIPTION OF EMBODIMENTS OF THE INVENTION

The invention relates generally to increasing the strength of glass. The glass having increased strength can be thin yet be sufficiently strong to be suitable for use in electronic devices, such as portable electronic devices.

The following detailed description is illustrative only, and is not intended to be in any way limiting. Other embodiments will readily suggest themselves to skilled persons having the benefit of this disclosure. Reference will now be made in detail to implementations as illustrated in the accompanying drawings.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application and business related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

Embodiments pertain to apparatus, systems and methods for improving strength of a thin glass member for an electronic device. In one embodiment, the glass member can have improved strength characteristics in accordance with a predetermined stress profile. The predetermined stress profile can be formed through multiple stages of chemical strengthening. The stages can, for example, have a first ion exchange stage where larger ions are exchanged into the glass member, and a second ion exchange stage where some of the larger ions are exchanged out from the glass member.

In one example, the glass member may be an outer surface of an electronic device. The glass member may for example correspond to a glass cover that helps form part of a display area of an electronic device (e.g., situated in front of a display either as a separate part or integrated within the display). Alternatively or additionally, the glass member may form a part of the housing. For example, it may form an outer surface other than in the display area.

The apparatus, systems and methods for improving strength of thin glass are especially suitable for glass covers, or displays (e.g., Liquid Crystal Display (LCD) displays), assembled in small form factor electronic devices such as handheld electronic devices (e.g., mobile phones, media players, personal digital assistants, remote controls, etc.). The apparatus, systems and methods can also be used for glass covers or displays for other relatively larger form factor electronic devices (e.g., portable computers, tablet computers, displays, monitors, televisions, etc.). The glass can be thin in these various embodiments, such as less than 5 mm or more particularly between 0.5 and 3 mm. In particularly thin embodiments, the thickness of the glass can be between 0.3 and 1 mm.

In one embodiment, a glass cover can extend to the edge of a housing of an electronic device without a protective bezel or other barrier. In one embodiment, the glass cover can include a bezel that surrounds its edges. In either cases, the edges are stronger by creating a specific edge geometry and/or chemical strengthening. The glass cover can be provided over or integrated with a display, such as a LCD display.

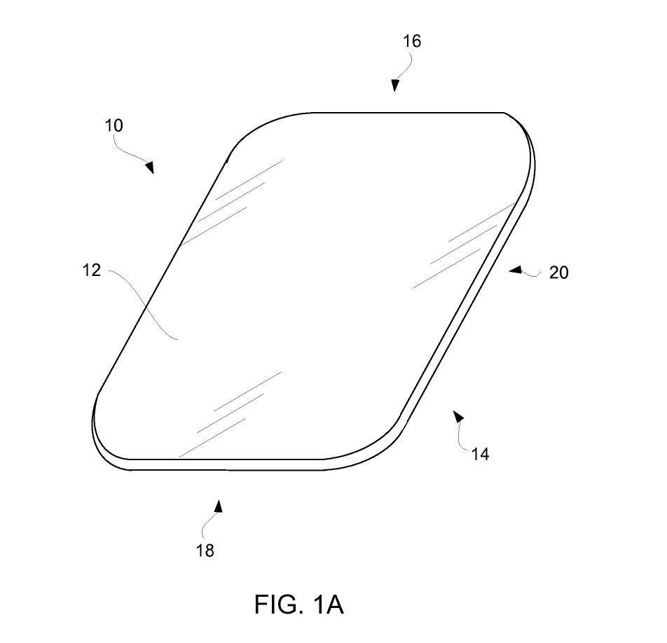

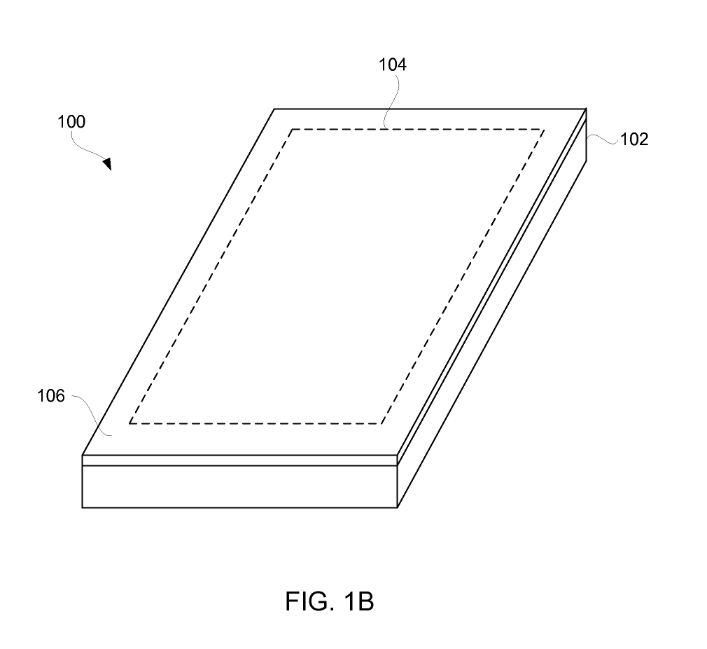

Embodiments of the invention are discussed below with reference to FIGS. 1A-10B. However, those skilled in the art will readily appreciate that the detailed description given herein with respect to these figures is for explanatory purposes as the invention extends beyond these limited embodiments.

The same reference indicators will generally be used throughout the drawings and the following detailed description to refer to the same or like parts. It should be appreciated that the drawings are generally not drawn to scale, and at least some features of the drawings have been exaggerated for ease of illustration.

FIG. 1A is a perspective diagram of glass member 10 in accordance with one embodiment. Glass member 10 is a thin sheet of glass. For example, the thickness of the glass in many applications is less or equal to 3 mm. The length, width or area for glass member 10 is dependent on the application. One application for glass member 10 is as a cover glass for a housing of an electronic device, such as a portable or handheld electronic device. As illustrated in FIG. 1A, glass member 10 can include front surface 12, back surface 14, top surface 16, bottom surface 18, and side surface 20. For enhanced strength, the edges or the sides (including top, bottom, left and right) can be formed in accordance with a predetermined geometry. Using chemical strengthening, the predetermined geometry at the edges can increase the strength of glass member 10 at the edges. The surfaces of glass member 10 can also be chemically strengthened. The use of the predetermined geometry can render the edges more receptive to chemical strengthening because mechanical stress relaxation is reduced. Chemically strengthening can, for example, be performed on glass member 10 by placing glass member 10 in one or more chemical solutions with which glass member 10 can interact, such as by ion exchange. As noted below, the predetermined geometry for the edges can provide smooth transitions (e.g., curved, rounded) in place of sharp transitions. In one embodiment, the glass member is a glass structure provided with or for a consumer electronic device. The glass member can be provided on an exterior or interior surface of the consumer electronic device. The glass structure can, in generally, be any part of the consumer electronic device that is made of glass. In one embodiment, the glass structure is at least a portion of a housing (e.g., outer surface) for the consumer electronic device.

FIG. 1B is a simplified diagram of electronic device 100 in accordance with one embodiment. Electronic device 100 may, for example, be embodied as portable or handheld electronic device having a thin form factor (or low profile). Electronic device 100 can, for example, correspond to a portable media player, a media storage device, a Portable Digital Assistant (PDA), a tablet PC, a computer, a mobile communication device (e.g., a cellular phone, a smart phone), a GPS unit, a remote control device, and the like. The electronic device 100 can be referred to as a consumer electronic device.

Electronic device 100 can include housing 102 that serves as the outer surface for electronic device 100. Electrical components (not shown) are disposed within housing 102. The electrical components can include a controller (or processor), memory, battery, and a display (e.g., LCD display). Display area 104 is disposed within housing 102 of electronic device 100. Electronic device 100 can include a full view or substantially full view display area 104 that consumes a majority if not all of the front surface of electronic device 100. Display area 104 may be embodied in a variety of ways. In one example, display area 104 consists of at least a display such as a flat panel display and more particularly an LCD display. Additionally, electronic device 100 has cover glass 106 provided over display area 104. Cover glass 106 server as an external surface, i.e., top surface, for electronic device 100. Cover glass 106 can be clear or transparent so that display area 104 can be viewed through cover glass 106. Cover glass 106 also resist scratching and therefore provide a substantially scratch-resistance surface for the top surface of housing 102 for electronic device 100.

Display area 104 may alternatively or additionally include a touch sensing device positioned over a display screen. For example, display area 104 may include one or more glass layers having capacitive sensing points distributed thereon. Each of these components can be separate layers or they may be integrated into one or more stacks. In one embodiment, cover glass 106 can act as the outer most layer of display area 104.

Any component of electronic 100 is susceptible to breakage if used in an abusive manner. For example, cover glass 106 can be a weak point of electronic device 100 in terms of strength against bending and damage if dropped. As a result, cover glass 106 can be susceptible to damage when electronic device 100 is stressed as for example in a drop event. By way of example, stress to cover glass 106 can result in damage, such as cracks or breaks.

Further, as shown in FIG. 1B, cover glass 106 can extend across the entire top surface of housing 102. In such a case, the edges of cover glass 106 are aligned, or substantially aligned, with the sides of housing 102. However, in other embodiments, the cover glass 106 need only be provided over a portion of a given surface of housing 102. In any case, given that the thickness of cover glass 106 is rather thin (i.e., less than a few millimeters), cover glass 106 can be cover glass 106 can be strengthened so as to reduce its susceptibility to damage.

First, the glass material for cover glass 106 can be selected from available glass that is stronger. For example, alumino silicate glass is one suitable choice for the glass material for cover glass 106. Other examples of glass materials include, but are not limited to including, soda lime, borosilicate, and the like.

Second, the glass material can be formed into an appropriate size, such as, for example, by singulating and/or machining. As an example, a sheet of the glass material can be cut into a plurality of individual cover glass pieces. The cover glass pieces can, for example, be suitably sized to fit on the top surface of housing 102 for electronic device 100.

In one embodiment, the edges of the cover glass pieces can be configured to correspond to a particular predetermined geometry. By forming (e.g., machining) the edges of the cover glass pieces to correspond to the particular predetermined geometry, the cover glass pieces become stronger and thus less susceptible to damage. Examples of suitable predetermined geometries for the edges (also known as edge geometries) of the cover glass pieces are discussed below. In one embodiment, the forming (e.g., machining) of the edges to correspond to a particular predetermined geometry can cause compressive stress at the edges to be more uniform. In other words, the compressive stress profile can be managed such that compressive minimum does not deviate much from the average compressive stress. Also, to the extent there is a minimum compressive stress, the predetermined geometry can serve to position the compressive minimum subsurface (i.e., slightly inward) from the edges. In one example, the edge geometry can include soft or gradual transitions from one surface to the other, as for example at interface between a first surface that is perpendicular to a second surface. Here, sharp corners or edges can be curved or otherwise smoothed such that they are less sharp. By rounding or smoothing the sharp corners or edges, as provided by the predetermined geometry, the cover glass pieces can become more receptive to more uniform chemical strengthening.

Third, regardless of whether any particular edge geometry is used, the cover glass pieces can be chemically treated for further strengthening. One suitable chemical treatment is to place the cover glass pieces in a chemical bath containing Alkali metal (e.g., KNO₃) ions for a period of time (e.g., several hours) at an elevated temperature. The chemical treatment can desirably result in higher compression stresses at the surface of the cover glass pieces. The depth of the compressive layer being formed can vary with the characteristics of the glass used and the specific chemical treatment. For example, the depth of the compressive layer being formed can, in some embodiments, range from a depth of the compressive layer can be about 10 micrometers for soda lime glass to a depth of about 100 micrometers for alumino silicate glass. More generally, the depth of the compressive layer can be from 10-90 micrometers for soda lime glass or alumino silicate glass. However, it should be understood that the depth of the compressive layer can vary depending on specific chemical treatment applied to the glass.

The surface of the cover glass pieces includes the edges of the cover glass pieces. The higher compression stresses may be the result of ion exchange at or near the surface of the cover glass. The surface of the cover glass pieces includes the edges of the cover glass pieces. The higher compression stresses may be the result of K⁺ ions effectively replacing some Na⁺ ions at or near the surface of the cover glass.

Small form factor devices, such as handheld electronic devices, typically include a display region (e.g., display area 104) that includes various layers. The various layers may include at least a display, and may additionally include a sensing arrangement disposed over (or integrated with) the display. In some cases, the layers may be stacked and adjacent one another, and may even be laminated thereby forming a single unit. In other cases, at least some of the layers are spatially separated and not directly adjacent. For example, the sensing arrangement may be disposed above the display such that there is a gap therebetween. By way of example, the display may include a Liquid Crystal Display (LCD) that includes a Liquid Crystal Module (LCM). The LCM generally includes at least an upper glass sheet and a lower glass sheet that at least partially sandwich a liquid crystal layer therebetween. The sensing arrangement may be a touch sensing arrangement such as those used to create a touch screen. For example, a capacitive sensing touch screen can include substantially transparent sensing points or nodes dispersed about a sheet of glass (or plastic). A cover glass can serve as the outer protective barrier for the display region. The cover glass is typically adjacent the display region but can also be integrated with the display region, such as another layer (outer protective layer) therefor.

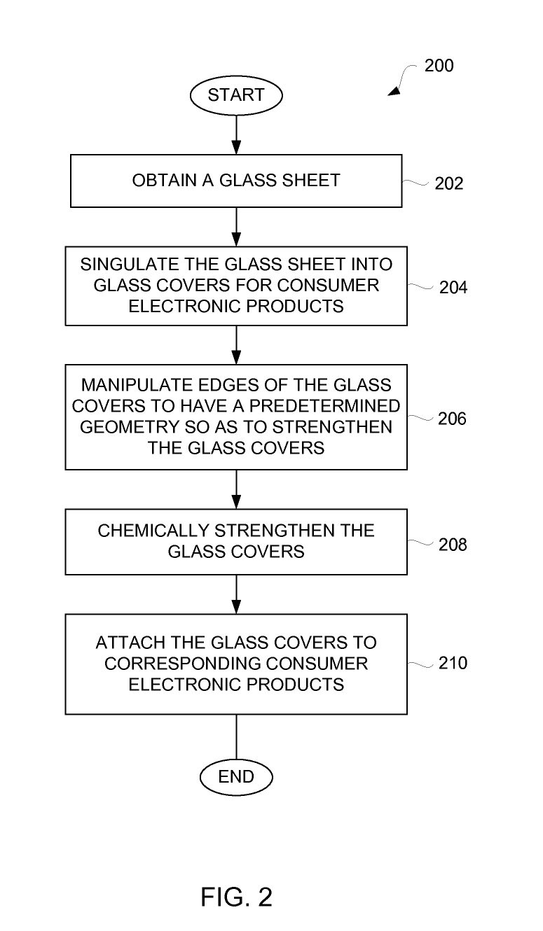

FIG. 2 is a flow diagram of glass cover process 200 according to one embodiment. Glass cover process 200 can, for example, be used to form one or more cover glass pieces. The glass cover pieces can, for example, be used for cover glass 106 illustrated in FIG. 1B.

Glass cover process 200 can initially obtain 202 a glass sheet. The glass sheet is, for example, alumino silicate glass. The glass sheet can then be processed to singulate 204 the glass sheet into individualized glass covers. The glass covers are, for example, used on consumer electronic products, such as electronic device 100 illustrated in FIG. 1B. In one embodiment, the glass sheet is cut (e.g., with a blade, scribe & break, water jet or laser) to singulate 204 the glass sheet into the individualized glass covers. In an alternative embodiment, the glass covers can be individually formed without requiring singulation.

Next, the edges of the individual glass covers can be manipulated 206 to have a predetermined geometry so as to strengthen the glass covers. Manipulation 206 of the edges can cause the edges to take the shape of the predetermined geometry. For example, manipulation 206 can machine, grind, cut, etch, scribe, mold, slump or otherwise form the edges of the glass covers into the predetermined geometry. The edges can also be polished.

Additionally or alternatively (to the manipulation 206), the individual glass covers can be chemically strengthened 208. In one embodiment, the glass cover can be placed in a chemical bath to allow chemical strengthening to occur. In this type of chemical strengthening, an ion exchange process occurs at the surface of the glass covers which serves to increase compressive stress at the surfaces, including the edges. Further, the chemical strengthening can use a series of chemical baths (i.e., stages) to form a desired compressive stress profile. In other words, through use of a series of chemical baths, a desired compressive stress profile can be engineered (i.e., induced) into a glass cover. The specifics of the desired stress profile can vary depending on application for the glass cover and the characteristics of the glass being used.

Thereafter, the glass covers can be attached 210 to corresponding consumer electronic products. The glass covers can form an outer surface of the corresponding consumer electronic product (e.g., top surface of a housing). Once attached 210, the edges of the glass covers can be exposed. Although the edges of the glass covers can be exposed, the edges can be further protected. As one example, the edges of the glass covers can be recessed (e.g., along one or more axes) from the outer sides of a housing for the consumer electronic product. As another example, the edges of the glass covers can be protected by additional material placed around or adjacent the edges of the cover glasses. The glass covers can be attached 210 in a variety of ways, including adhesive, bonding, or mechanical devices (e.g., snaps, screws, etc.). In some embodiments, the glass covers can also have a display module (e.g., LCM) attached. Following attachment 210 of the glass covers to the consumer electronic products, glass cover process 200 can end.

Although manipulation 206 of the edges of the glass covers can manipulate 206 all of the edges of the glass covers, it should be noted that not all of the edges need to be manipulated 206. In other words, depending on the particular embodiment or design, manipulation 206 can be imposed on only one or more of the edges of the glass covers. For a given edge, all or a portion of the edge can be manipulated into a predetermined geometry. Also, different edges can be manipulated 206 differently (i.e., different edges can have different geometries). Also, some edges can a predetermined geometry while other edges can remain sharp. Over a given edge being manipulated 206, the predetermined geometry can also vary, such as with a complex curve (e.g., s-curve).

Singulation 204 of the glass sheet into individual glass covers can be performed in a manner that reduces microcracks and/or stress concentrations at the edges, thereby increasing overall strength. The singulation technique used can vary and can be dependent on the thickness of the glass sheet. In one embodiment, the glass sheet is singulated using a laser scribe process. In another embodiment, the glass sheet is singulated using a mechanical scribing technique, such as where a mechanical cutting wheel may be used.

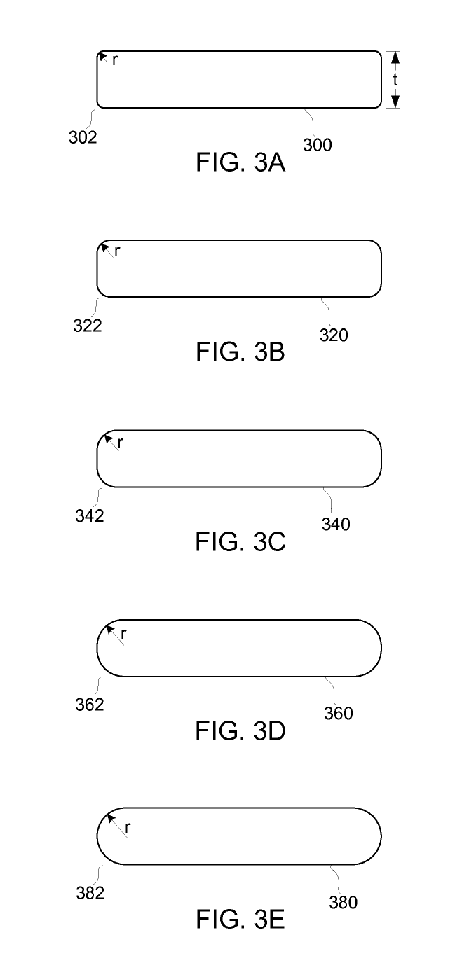

FIGS. 3A-3E are cross-sectional diagrams of glass covers for electronic device housings according to various embodiments. The cross-sectional diagrams illustrate certain predetermined edge geometries that can be used for glass covers to be provided on electronic device housings. It should be appreciated that the edge geometries shown are by way of example, and are not to be construed as being limiting. The width and thickness depicted in FIGS. 3A-3B are not to scale for purposes of illustration.

FIG. 3A illustrates a cross-sectional diagram of glass cover 300 having edge geometry 302. The thickness (t) for the glass cover is about 1.0 millimeter although it should be appreciated that thickness (t) may vary. Edge geometry 302 can have a small edge radius (r) of, for example, about 0.1 millimeters. Here, the edges of the edge geometry 302 are rounded to an edge radius of 10% of the thickness of the cover glass.

FIG. 3B illustrates a cross-sectional diagram of glass cover 320 having edge geometry 322. The thickness (t) for the glass cover is about 1.0 millimeter although it should be appreciated that thickness (t) may vary. Edge geometry 322 can have an edge radius of, for example, about 0.2 millimeters. Here, the edges of the edge geometry 322 are rounded to an edge radius of 20% of the thickness of the cover glass.

FIG. 3C illustrates a cross-sectional diagram of a glass cover 340 having edge geometry 342. The thickness (t) for the glass cover is about 1.0 millimeter although it should be appreciated that thickness (t) may vary. Edge geometry 342 can have a medium edge radius of, for example, about 0.3 millimeters. Here, the edges of the edge geometry 342 are rounded to an edge radius of 30% of the thickness of the cover glass.

FIG. 3D illustrates a cross-sectional diagram of glass cover 360 having edge geometry 362. The thickness (t) for the glass cover is about 1.0 millimeter although it should be appreciated that thickness (t) may vary. Edge geometry 362 can have a large edge radius (r) of, for example, about 0.4 millimeters. Here, the edges of the edge geometry 362 are rounded to an edge radius of 50% of the thickness of the cover glass.

FIG. 3E illustrates a cross-sectional diagram of a glass cover 380 having an edge geometry 382. The thickness (t) for the glass cover is about 1.0 millimeter although it should be appreciated that thickness (t) may vary. The edge geometry 382 can have a full edge radius (r) of, for example, about 0.5 millimeters. Here, the edges of the edge geometry 382 are rounded to an edge radius of 50% of the thickness of the cover glass.

In general, the predetermined edge geometries illustrated in FIGS. 3A-3E serve to round the edges of a glass cover. By eliminating sharp edges on the glass cover, the strength of the glass cover is able to be increased. Specifically, rounding otherwise sharp edges improves strength of the edges, thereby strengthening the edges which would otherwise be weak regions of a glass cover. The edges are able to be strengthened so that compressive stress of the glass cover is generally uniform over its surface, even at the edges. In general, the larger the edge radius, the more uniform the strengthening can be over the surface of the glass cover, and thus the greater the strength can be. However, chemical strengthening can be performed to form a stress profile that is intentionally non-uniform.

Besides the rounding of the edges illustrated in FIGS. 3A-3E, the edges of a glass cover can be machined in ways other than through rounding. As one example, edge geometries can pertain to flattening of the edges. As another example, edge geometries can be complex geometries. One example of a complex geometry is a spline curve. Another example of a complex geometry is an s-curve.

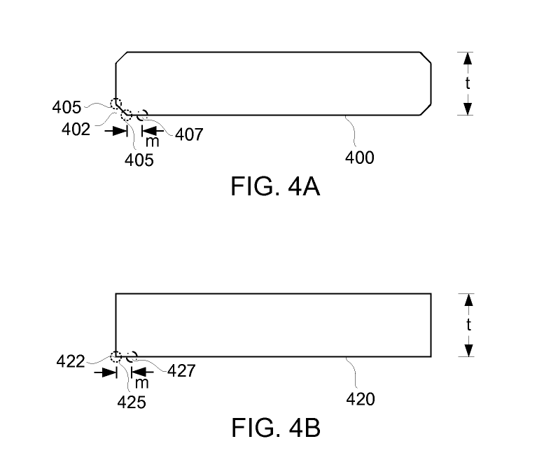

FIG. 4A is a cross-sectional diagram of a glass cover for an electronic device housings according to an additional embodiment that pertains to a chamfered edge geometry. More particularly, FIG. 4A illustrates a cross-sectional diagram of glass cover 400 having edge geometry 402. The thickness (t) for the glass cover is about 1.0 millimeter. Edge geometry 402 has flattened edges. Edge geometry 402 is effectively a chamfered edge. A chamfer is a beveled edge that substantially connects two sides or surfaces. In one embodiment, a chamfered edge may have a depth of between approximately 0.15 millimeters and approximately 0.25 millimeters. By way of example, edge geometry 402 may include an approximately 0.15 millimeter chamfer or an approximately 0.25 millimeter chamfer. By providing the chamfered edge, substantially minimum compressive stresses may occur approximately at locations 405. One location which corresponds to a substantially minimum Van Mises stress location is indicated at a location 407. In one embodiment, location 407 is substantially centered at approximately ten (10) micrometers from a corner associated with edge geometry 402. In other words, moving the minimum compressive stress inward from the edge (e.g., corner), such as by use of edge geometry 402, can render the edge stronger. If the flattened edges are also rounded, such as on the order illustrated in FIGS. 3A-3E, the flattened edges (e.g., locations 405) can be more uniformly chemically strengthened.

FIG. 4B illustrates a cross-sectional diagram of glass cover 420 having reference edge geometry 422 that includes a straight corner (i.e., sharp corner). While this edge geometry does not yield the strength enhancement of the predetermined edge geometries, such as in FIGS. 3A-3E. The thickness (t) for the glass cover is about 1.0 millimeter although it should be appreciated that thickness (t) may vary. Reference edge geometry 422 is a straight corner, e.g., an approximately 90 degree corner. With reference edge geometry 422, an area of substantially minimum compressive stress occurs at location 425. One location which corresponds to a substantially minimum Van Mises stress location is indicated at location 427. In one embodiment, location 427 is substantially centered at approximately ten micrometers from a corner associated with the reference edge geometry 422. In comparing the location of the substantially minimum Van Mises stress location of FIGS. 4A and 4B, location 407 is further from the edge that the location 427.

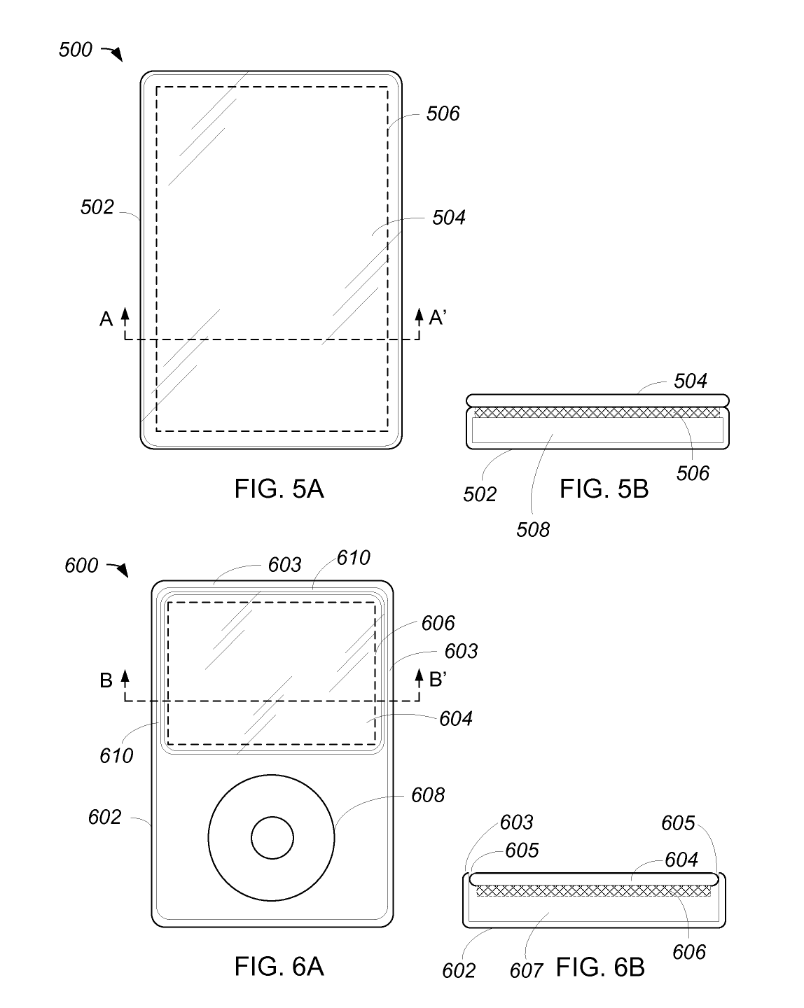

As previously discussed, glass covers can be used as an outer surface of portions of a housing for electronic devices, e.g., handheld electronic devices. A handheld electronic device may, for example, function as a media player, phone, internet browser, email unit or some combination of two or more of such. A handheld electronic device generally includes a housing and a display area. With reference to FIGS. 5A, 5B, 6A and 6B, different handheld electronic devices having cover glass (or glass windows) may be assembled in accordance with embodiments described herein. By way of example, the handheld electronic devices may correspond to an iPhone™ or iPod™ manufactured by Apple Inc. of Cupertino, Calif.

The strengthened glass, e.g., glass covers or cover windows, is particularly useful for thin glass applications. For example, the thickness of a glass cover being strengthen can be between about 0.5-2.5 mm. In other embodiments, the strengthening is suitable for glass products whose thickness is less than about 2 mm, or even thinner than about 1 mm, or still even thinner than about 0.6 mm.

The techniques for strengthening glass, e.g., glass covers or cover windows, are particularly useful for edges of glass that are rounded by a predetermined edge geometry having a predetermined edge radius (or predetermined curvature) of at least 10% of the thickness applied to the corners of the edges of the glass. In other embodiments, the predetermined edge radius can be between 20% to 50% of the thickness of the glass. A predetermined edge radius of 50% can also be considered a continuous curvature (or fully rounded), one example of which is illustrated in FIG. 3E. Alternatively, the strengthened glass, e.g., glass covers or cover windows, can be characterized such that, following the strengthening, the glass has a strength that is substantially uniform across the surface of the glass, including the edges. For example, in one embodiment, the strength reduction at the edges of the glass is no more than 10% lower than the strength of the glass at other non-edge portions. As another example, in another embodiment, the strength reduction at the edges of the glass is no more than 5% lower than the strength of the glass at other non-edge portions.

In one embodiment, the size of the glass cover depends on the size of the associated electronic device. For example, with handheld electronic devices, the size of the glass cover is often not more than five (5) inches (about 12.7 cm) diagonal. As another example, for portable electronic devices, such as smaller portable computers or tablet computers, the size of the glass cover is often between four (4) (about 10.2 cm) to twelve (12) inches (about 30.5 cm) diagonal. As still another example, for portable electronic devices, such as full size portable computers, displays or monitors, the size of the glass cover is often between ten (10) (about 25.4 cm) to twenty (20) inches (about 50.8 cm) diagonal or even larger.

However, it should be appreciated that in some cases with larger screen sizes, the thickness of the glass layers may need to be greater. The thickness of the glass layers may need to be increased to maintain planarity of the larger glass layers. While the displays can still remain relatively thin, the minimum thickness may increase with increasing screen size. For example, the minimum thickness of the glass cover can correspond to about 0.4 mm for small handheld electronic devices, about 0.6 mm for smaller portable computers or tablet computers, about 1.0 mm or more for full size portable computers, displays or monitors, again depending on the size of the screen. The thickness of the glass cover can, however, depend on the application, structure and/or the size of an electronic device.

FIGS. 5A and 5B are diagrammatic representations of electronic device 500 according to one embodiment. FIG. 5A illustrates a top view for the electronic device 500, and FIG. 5B illustrates a cross-sectional side view for electronic device 500 with respect to reference line A-A′. Electronic device 500 can include housing 502 that has glass cover window 504 (glass cover) as a top surface. Cover window 504 is primarily transparent so that display assembly 506 is visible through cover window 504. In one embodiment, the cover window 504 can be strengthened using any of the techniques described herein. Display assembly 506 can, for example, be positioned adjacent cover window 504. Housing 502 can also contain internal electrical components besides the display assembly, such as a controller (processor), memory, communications circuitry, etc. Display assembly 506 can, for example, include a LCD module. By way of example, display assembly 506 may include a Liquid Crystal Display (LCD) that includes a Liquid Crystal Module (LCM). In one embodiment, cover window 504 can be integrally formed with the LCM. Housing 502 can also include an opening 508 for containing the internal electrical components to provide electronic device 500 with electronic capabilities. In one embodiment, housing 502 may need not include a bezel for cover window 504. Instead, cover window 504 can extend across the top surface of housing 502 such that the edges of cover window 504 can be aligned (or substantially aligned) with the sides of housing 502. The edges of cover window 504 can remain exposed. Although the edges of cover window 504 can be exposed as shown in FIGS. 5A and 5B, in alternative embodiment, the edges can be further protected. As one example, the edges of cover window 504 can be recessed (horizontally or vertically) from the outer sides of housing 502. As another example, the edges of cover window 504 can be protected by additional material placed around or adjacent the edges of cover window 504.

Cover window 504 may generally be arranged or embodied in a variety of ways. By way of example, cover window 504 may be configured as a protective glass piece that is positioned over an underlying display (e.g., display assembly 506) such as a flat panel display (e.g., LCD) or touch screen display (e.g., LCD and a touch layer). Alternatively, cover window 504 may effectively be integrated with a display, i.e., glass window may be formed as at least a portion of a display. Additionally, cover window 504 may be substantially integrated with a touch sensing device such as a touch layer associated with a touch screen. In some cases, cover window 504 can serve as the outer most layer of the display.

FIGS. 6A and 6B are diagrammatic representations of electronic device 600 according to another embodiment of the invention. FIG. 6A illustrates a top view for electronic device 600, and FIG. 6B illustrates a cross-sectional side view for electronic device 600 with respect to reference line B-B′. Electronic device 600 can include housing 602 that has glass cover window 604 (glass cover) as a top surface. In this embodiment, cover window 604 can be protected by side surfaces 603 of housing 602. Here, cover window 604 does not fully extend across the top surface of housing 602; however, the top surface of side surfaces 603 can be adjacent to and aligned vertically with the outer surface of cover window 604. Since the edges of cover window 604 can be rounded for enhanced strength, there may be gaps 605 that are present between side surfaces 603 and the peripheral edges of cover window 604. Gaps 605 are typically very small given that the thickness of cover window 604 is thin (e.g., less than 3 mm). However, if desired, gaps 605 can be filled by a material. The material can be plastic, rubber, metal, etc. The material can conform in gap 605 to render the entire front surface of electronic device 600 flush, even across gaps 605 proximate the peripheral edges of cover window 604. The material filling gaps 605 can be compliant. The material placed in gaps 605 can implement a gasket. By filling the gaps 605, otherwise probably undesired gaps in the housing 602 can be filled or sealed to prevent contamination (e.g., dirt, water) forming in the gaps 605. Although side surfaces 603 can be integral with housing 602, side surface 603 could alternatively be separate from housing 602 and, for example, operate as a bezel for cover window 604.

Cover window 604 is primarily transparent so that display assembly 606 is visible through cover window 604. Display assembly 606 can, for example, be positioned adjacent cover window 604. Housing 602 can also contain internal electrical components besides the display assembly, such as a controller (processor), memory, communications circuitry, etc. Display assembly 606 can, for example, include a LCD module. By way of example, display assembly 606 may include a Liquid Crystal Display (LCD) that includes a Liquid Crystal Module (LCM). In one embodiment, cover window 604 is integrally formed with the LCM. Housing 602 can also include an opening 607 for containing the internal electrical components to provide electronic device 600 with electronic capabilities.

The front surface of electronic device 600 can also include user interface control 608 (e.g., click wheel control). In this embodiment, cover window 604 does not cover the entire front surface of electronic device 600. Electronic device 600 essentially includes a partial display area that covers a portion of the front surface.

Cover window 604 may generally be arranged or embodied in a variety of ways. By way of example, cover window 604 may be configured as a protective glass piece that is positioned over an underlying display (e.g., display assembly 606) such as a flat panel display (e.g., LCD) or touch screen display (e.g., LCD and a touch layer). Alternatively, cover window 604 may effectively be integrated with a display, i.e., glass window may be formed as at least a portion of a display. Additionally, cover window 604 may be substantially integrated with a touch sensing device such as a touch layer associated with a touch screen. In some cases, cover window 604 can serve as the outer most layer of the display.

As noted above, the electronic device can be a handheld electronic device or a portable electronic device. The invention can serve to enable a glass cover to be not only thin but also adequately strong. Since handheld electronic devices and portable electronic devices are mobile, they are potentially subjected to various different impact events and stresses that stationary devices are not subjected to. As such, the invention is well suited for implementation of glass surfaces for handheld electronic device or a portable electronic device that are designed to be thin.

As discussed above, glass cover or, more generally, a glass piece may be chemically treated such that surfaces of the glass are effectively strengthened. Through such strengthening, glass pieces can be made stronger and tougher so that thinner glass pieces can be used with consumer electronic device. Thinner glass with sufficient strength allows for consumer electronic device to become thinner.

A glass cover or, more generally, a glass piece may be chemically treated such that surfaces, including edges, of the glass are effectively strengthened. For example, in a single exchange process, some Na⁺ ions near the surface regions of the glass piece may be replaced by Alkali metal ions (e.g., K⁺ ions) to strengthen the surface regions. When Alkali metal ions, which are typically larger than Na+ions, replace Na⁺ ions, a compressive layer is effectively generated near the surface and, hence, the edges of a glass cover. Thus, the glass cover is essentially made stronger at the surface.

In addition to chemically strengthening the glass, the glass may be chemically toughened as well. In a double exchange process, once the Alkali metal ions replace certain of the Na⁺ ions, the Alkali metal ions (e.g., K⁺ ions) closest to the outside surfaces of the glass piece, e.g., the top surface regions, may be replaced by Na⁺ ions in order to remove some compression stresses from near the top surface regions, while underlying Alkali metal ions previously exchanged into the glass piece may remain in the lower surface regions. In addition to providing a reduced compressive surface stress for the glass cover, the double exchange process may further provide a reduced central tension for the glass cover. The second exchange process can thus serve to chemically toughen the glass.

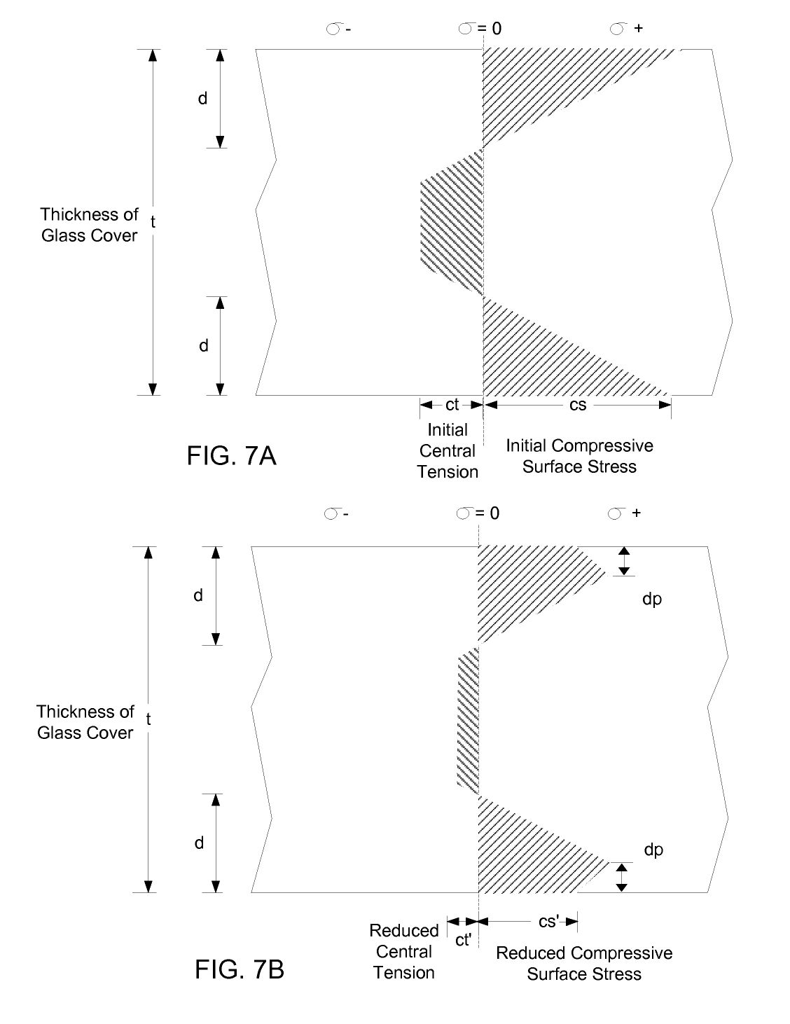

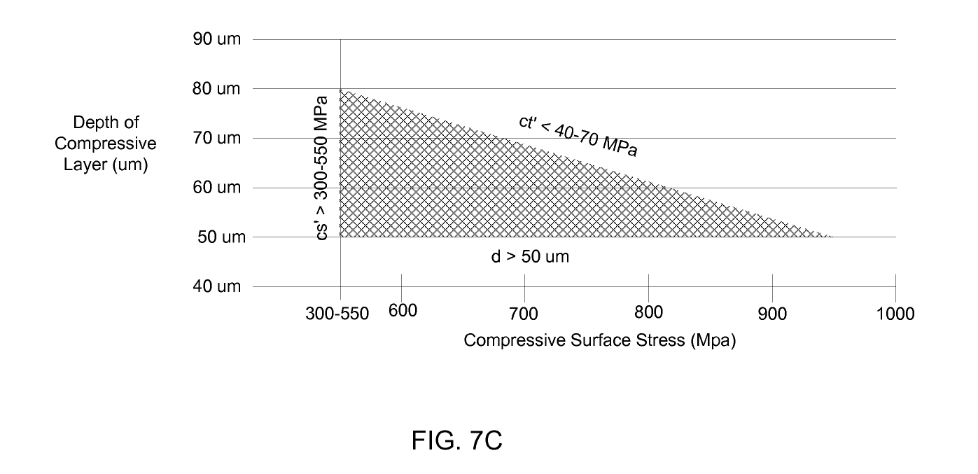

FIG. 7A is a diagram of a partial cross-sectional view of a glass cover, which shows an initial tension/compression stress profile according to one embodiment. The initial tension/compression stress profile may result from an initial exchange process to strengthen the surface regions of the glass cover. In legends disposed along a top horizontal dimension of the diagram, a lower case Greek letter sigma is used. A minus sigma legend indicates a profile region of tension. A plus sigma legend indicates profile regions of compression. A vertical dashed line and a sigma-equals-zero legend designates crossover between compression and tension.

In the partial cross-sectional view of the glass cover shown in FIG. 7A, thickness (t) of the glass cover is shown. Initial compressive surface stress (cs) of the initial tension/compression stress profile is shown at the surface of the cover glass shown in FIG. 7A. The compressive stress for the cover glass has a compressive stress layer depth (d) as shown in FIG. 7A. The compressive stress layer depth (d) extends from surfaces of the glass cover towards a central region as shown in the cross-section view of the glass cover depicted in FIG. 7A. Initial central tension (ct) of the initial tension/compression stress profile is at the central region of the glass cover as shown in FIG. 7A.

As shown in FIG. 7A, the initial compressive stress has a profile with peaks at the surfaces of the glass cover. That is, the initial compressive surface stress (cs) is at its peak at the surface of the cover glass. The initial compressive stress profile shows decreasing compressive stress as the compressive stress layer depth extends from surfaces of the glass cover towards the central region of the glass cover. The initial compressive stress continues to decrease going inwards until crossover between compression and tension. In the diagram FIG. 7A, regions of the decreasing profile of the initial compressive stress are highlighted using right-to-left diagonal hatching.

After crossover between compression and tension, a profile of the initial central tension (ct) extends into the central region shown in the cross-section view of the glass cover. In the diagram FIG. 7A, the profile of the initial central tension (ct) extending into the central region is highlighted using left to right diagonal hatching.

FIG. 7B is a diagram of a partial cross-sectional view of a glass cover, which shows a reduced tension/compression stress profile according to one embodiment. The reduced tension/compression stress profile may result from a double exchange process, and particularly from chemically toughening the glass. Reduced compressive surface stress (cs′) of the reduced tension/compression stress profile is shown in FIG. 7B. In FIG. 7B, compressive stress layer depth (d) now corresponds to the reduced compressive stress. In addition, reduced central tension (ct′) is shown in the central region, in the reduced tension/compression stress profile of the glass cover.

In FIG. 7B, the reduced compressive surface stress shows submerged profile peaks, below the surfaces of the glass cover. Depth (dp) of the submerged profile peaks varies depending thickness of the glass cover as well as on glass characteristics. For example, in one embodiment, the depth (dp) of the peak of the compressive stress may be substantially within a range of approximately five (5) to fifty (50) microns. In another embodiment, the depth (dp) of the peak of the compressive stress may be substantially within a range of approximately ten (10) to thirty (30) microns. It should be understood that, as a tradeoff for reducing compressive surface stress (e.g., from (cs) to (cs′)), the magnitude of the reduced compressive stress at the depth (dp) of the compressive stress shown in FIG. 7B is greater than the magnitude of the initial compressive stress at the depth (dp) of the initial compressive stress shown in FIG. 7A.

In light of the foregoing, it should be understood that the reduced compressive surface stress (cs′) shows increasing profiles as the compressive surface layer depth extends from surfaces of the glass cover and towards the submerged profile peaks. Such increasing profiles of compressive stress may be advantageous in arresting cracks. Within the depth (dp) of the submerged profile peaks (dp), as a crack attempts to propagate from the surface of the cover glass, deeper into the cover glass, it is met with increasing compressive stress, which may provide crack arresting action (i.e., which may stop propagation of the crack). Additionally, as shown in FIG. 7B, extending from the submerged profile peaks further inward towards the central region, the reduced compressive stress turns to provide a decreasing profile until crossover between compression and tension. In FIG. 7B, regions of profiles of the reduced compressive stress are highlighted using right-to-left diagonal hatching.

After crossover between compression and tension, a profile of the reduced central tension (ct′) extends into the central region shown in the cross-section view of the glass cover illustrated in FIG. 7B. In the diagram FIG. 7B, the profile of the reduced central tension (ct′) extending into the central region is highlighted using left to right diagonal hatching.

Initial central tension substantially in excess of a predetermined tension limit may disadvantageously promote fracturing of the glass cover. Reducing the initial central tension relative to the predetermined tension limit may advantageously inhibit (e.g., limit) fracturing of the glass cover. Comparison of FIG. 7A to FIG. 7B highlights that a double exchange process may reduce the initial central tension (ct) shown in FIG. 7A so as to provide a reduced central tension (ct′). For example, the double exchange process may reduce an initial central tension (ct) substantially below a predetermined tension limit so as to provide the reduced central tension (ct′), such as on the order of forty (40) to seventy (70) Mega Pascals (MPa), for example.

In the glass cover, initial central tension (ct) may be substantially linearly related to initial compressive surface stress (cs); and reduced central tension (ct′) may be substantially linearly related to reduced compressive surface stress (cs′). This may be estimated in mathematical relations as ct=(cs−d)/(t−2d) and ct′=(cs′−d)/(t−2d), wherein t is the thickness of the glass cover, and d is the compressive surface layer depth. Accordingly, it should be understood that reducing the initial compressive surface stress (cs) shown in FIG. 7A to the reduced compressive surface stress (cs′) shown in FIG. 7B is related to reducing the initial central tension (ct) shown in FIG. 7A to the reduced central tension (ct′) shown in FIG. 7B.

While reducing the initial central tension (ct) may be desirable to advantageously limit fracturing of the glass cover, reducing the initial compressive surface stress (cs) to the reduced compressive surface stress (cs′) reduces an enhanced surface strength, which was provided by the initial exchange process. Accordingly, it may be advantageous to limit reduction of the initial compressive surface stress in the double exchange process, so as to produce a limited reduction of the enhanced surface strength. Further, it should be understood that the chemical toughening treatment of the sodium bath may be employed over a period of time. The period of time of the chemical toughening treatment may be limited, for example, to a duration of approximately one half hour or less, so as to produce the limited reduction in the enhanced surface strength of the glass cover.

Comparison of FIG. 7A to FIG. 7B highlights limiting reduction of the initial compressive surface stress (cs) shown in FIG. 7A in the double exchange process relative to a preselected compressive value, so that the reduced compressive surface stress (cs′) shown in FIG. 7B remains substantially greater than a pre-chemically strengthened compressive value. For example, limiting reduction of an initial compressive surface stress (cs) shown in FIG. 7A in the double exchange process to a compressive value substantially within a range from approximately five-hundred (500) to nine-hundred (900) MPa, so that the reduced compressive surface stress (cs′) shown in FIG. 7B still remains substantially strengthened by the initial exchange process, such as the reduced compressive surface stress (cs′) being three-hundred (300) to five-hundred (500) MPa.

FIG. 7C is a diagram of compressive surface stress versus compressive surface layer depth, which shows a triangular continuum of intersecting ranges for reduced central tension, reduced compressive surface stress and compressive surface layer depth for the glass cover. The glass cover may be chemically strengthened for a sufficient period of time (for example for approximately six hours or more in a heated bath of KNO₃), so that the compressive surface layer depth of the glass cover is substantially greater than a preselected compressive surface layer depth value. For example, as shown in FIG. 7C, the glass cover may be chemically strengthened for a sufficient period of time, so that the compressive surface layer depth (d) of the glass cover is greater than approximately fifty (50) microns. This is illustrated in the diagram of FIG. 7C with a horizontal legend d>50 um, which is disposed along a horizontal extent of the triangular continuum.

In one embodiment, a predetermined compressive value design limit, for example, substantially within a range from approximately three-hundred (300) MPa to five hundred-and-fifty (550) MPa, the reduced compressive surface stress (cs′) shown in FIG. 7C may be substantially greater than the predetermined compressive value design limit. This is illustrated in the diagram of FIG. 7C with a vertical legend cs′>300-550 MPa, which is disposed along a vertical extent of the triangular continuum.

Also, in one embodiment, utilizing a predetermined tension design limit, for example, substantially within the range of approximately forty (40) to seventy (70) MPa, the reduced central tension (ct′) shown in FIG. 7C may be substantially less than the predetermined tension limit. As mentioned previously herein, in the glass cover, reduced central tension (ct′) may be linearly related to the reduced compressive surface stress (cs′). The foregoing is illustrated in the diagram of FIG. 7C with a legend ct′<40-70 MPa, which is disposed along a hypotenuse extent of the triangular continuum. In FIG. 7C hatching is used to highlight the triangular continuum of intersecting ranges for reduced central tension, reduced compressive surface stress and compressive surface layer depth for the glass cover.

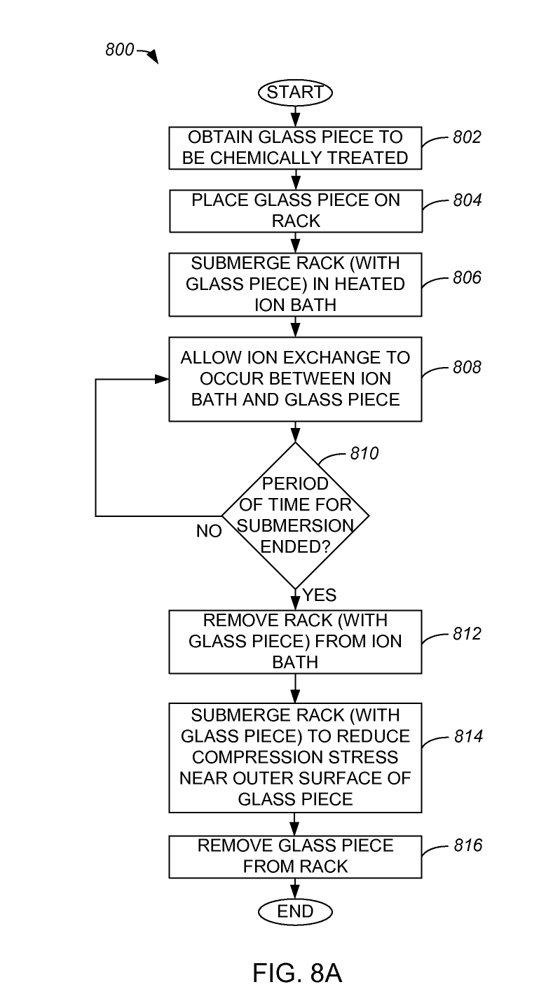

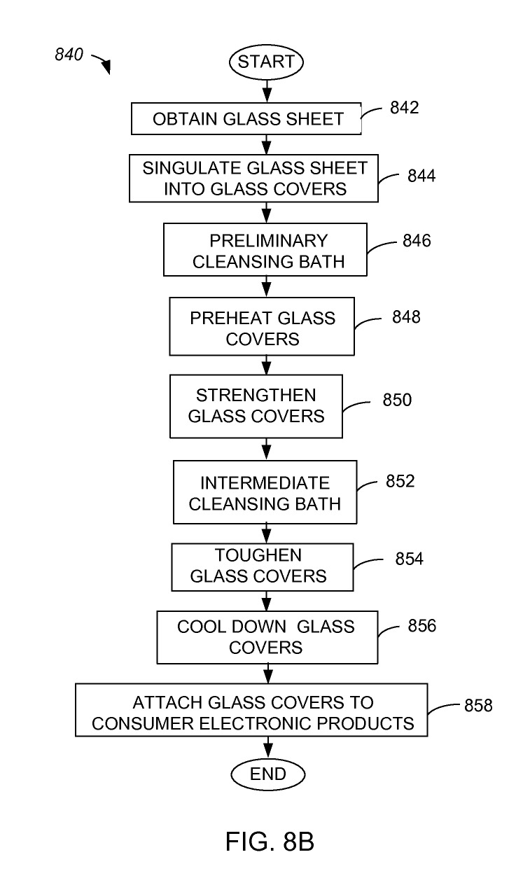

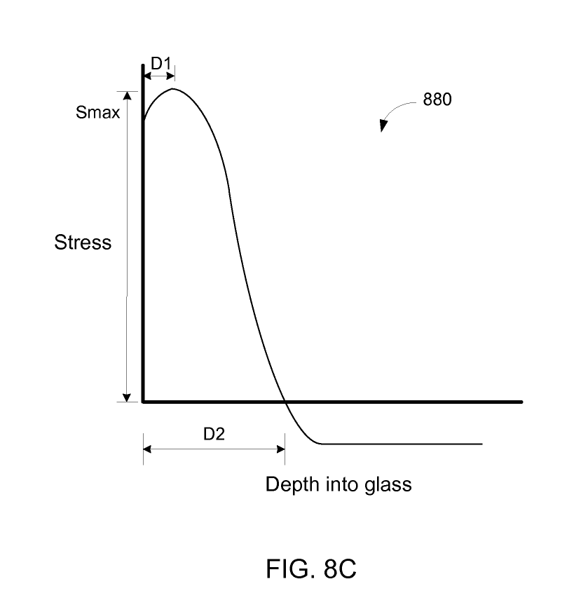

FIG. 8A illustrates a process 800 of chemically treating surfaces of a glass piece in accordance with one embodiment. As an example, the glass piece can pertain to a cover glass for a portion of a housing for a portable electronic device. The process 800 serves to strengthen the glass piece.

The process 800 of chemically treating surfaces, e.g., edges, of a glass piece can begin at step 802 in which the glass piece is obtained. The glass piece may be obtained, in one embodiment, after a glass sheet is singulated into glass pieces, e.g., glass covers, and the edges of the glass pieces are manipulated to have a predetermined geometry. It should be appreciated, however, that a glass piece that is to be chemically treated may be obtained from any suitable source.

In step 804, the glass piece can be placed on a rack. The rack is typically configured to support the glass piece, as well as other glass pieces, during chemical treatment. Once the glass piece is placed on the rack, the rack can be submerged in a heated ion bath in step 806. The heated ion bath may generally be a bath which includes a concentration of ions (e.g., Alkali metal ions, such as Lithium, Cesium or Potassium). It should be appreciated that the concentration of ions in the bath may vary, as varying the concentration of ions allows compression stresses on surfaces of the glass to be controlled. The heated ion bath may be heated to any suitable temperature to facilitate ion exchange. By way of example, the heated ion bath may be heated to between approximately 370 degrees Celsius and approximately 430 degrees Celsius.

After the rack is submerged in the heated ion bath, an ion exchange is allowed to occur in step 808 between the ion bath and the glass piece held on the rack. A diffusion exchange occurs between the glass piece, which generally includes Na⁺ ions, and the ion bath. During the diffusion exchange, Alkali metal ions, which are larger than Na⁺ ions, effectively replace the Na⁺ ions in the glass piece. In general, the Na⁺ ions near surface areas of the glass piece may be replaced by the Alkali ions, while Na⁺ ions are essentially not replaced by Alkali ions in portions of the glass which are not surface areas. As a result of the Alkali ions replacing Na⁺ ions in the glass piece, a compressive layer is effectively generated near the surface of the glass piece. The Na⁺ ions which have been displaced from the glass piece by the Alkali metal ions become a part of the ion solution.

A determination can be made in step 810 as to whether a period of time for submerging the rack in the heated ion bath has ended. It should be appreciated that the amount of time that a rack is to be submerged may vary widely depending on implementation. For example, the amount of time may depend upon whether the submersion of the rack and, hence, the thickness and characteristics of the glass piece. If the submersion of the rack in the heated ion bath is part of a double exchange process, then the period of time for submerging the rack in the potassium bath may be less than approximately six (6) hours. Typically, the longer a rack is submerged, i.e., the higher the exchange time for Alkali metal ions and Na⁺ ions, the deeper the depth of the chemically strengthened layer. For example, with thickness of the glass sheet being on the order of 1 mm, the chemical processing (i.e., ion exchange) provided in the ion bath can be provide into the surfaces of the glass pieces at a depth of ten (10) microns or more. For example, if the glass pieces are formed from soda lime glass, the depth of the compression layer due to the ion exchange can be about ten (10) microns. As another example, if the glass pieces are formed from alumino silicate glass, the depth of the compression layer due to the ion exchange can range from about fifty (50) microns to one-hundred (100) microns.

If the determination in step 810 is that the period of time for submerging the rack in the heated ion bath has not ended, then process 800 flow can return to step 817 in which the chemical reaction is allowed to continue to occur between the ion bath and the glass piece. Alternatively, if it is determined that the period of time for submersion has ended, then the rack can be removed from the ion bath in step 812.

As previously mentioned, the chemical strengthening provided by the process 800 uses a double exchange process. With the chemical strengthening being a double exchange process, the chemically strengthened layer of the glass piece may be chemically treated to effectively remove some or all Alkali metal ions (e.g., K⁺ ions) from near the surface of the chemically strengthened layer, while enabling other Alkali metal ions (e.g., K⁺ ions) to remain substantially beneath the surface of the chemically strengthened layer. A double exchange process may generally increase the reliability of the glass piece.

Thereafter, the process 800 moves from step 812 to optional step 814 in which the rack is submerged in a sodium bath for a predetermined amount of time in order to reduce compression stresses near surface of the glass piece or, more specifically, near the surface of the chemically strengthened layer of the glass piece. The sodium bath may be a sodium nitrate (NaNO₃) bath. The Na⁺ ions in the sodium bath may replace, via diffusion, at least some of the Alkali metal ions (e.g., K⁺ ions) near the surface of the chemically strengthened layer of the glass piece. In one embodiment, the sodium bath is a second heated bath that can operate to back-exchange a portion of the previously exchanged Alkali metal ions with sodium ions. That is, Na⁺ ions diffuse into the glass piece, while only a portion of the Alkali metal ions previously diffused into the glass piece diffuse out.

The amount of time the rack and, hence, the glass piece remains submerged in the sodium bath may vary depending, for example, on the depth to which Na⁺ ions are to replace Alkali metal ions (e.g., K⁺ ions) in the chemically strengthened layer of the glass piece. The amount of time the rack remains submerged in the glass piece may be dependent upon the amount of time the rack was previously submerged in the heated ion bath (e.g., potassium bath). For instance, a total amount of time the rack is submerged in the heated ion bath (e.g., potassium bath) and the sodium bath may be approximately 3-25 hours. By way of example, the rack may be submerged in the heated ion bath for approximately 5.75 hours while the rack may be submerged in the sodium bath for approximately 0.25 hours. In general, the or the rack may be submerged in the heated ion bath for approximately 4-20 hours, while the rack may be submerged in the sodium bath for up to approximately two hours.

Upon removing the rack from the sodium bath, the glass piece may be removed from the rack in step 816, and the process 800 of chemically treating surfaces of a glass piece can be completed. After the glass piece is removed from the rack in step 816, the process 800 of chemically treating surfaces of a glass piece can be completed. However, if desired, the glass piece can be polished. Polishing can, for example, remove any haze or residue on the glass piece following the chemical treatment.

FIG. 8B is another flow diagram which illustrates a process 840 of strengthening and toughening glass covers according to one embodiment. The process 840 of strengthening and toughening glass covers may begin at step 842 in which a glass sheet is obtained. The process 840 may continue by singulating 844 the glass sheet into a plurality of glass covers, wherein each of the glass covers may be suitably sized, so as to be provided on the exposed surface of a consumer electronic product.

The process 840 may continue with chemically pre-treated the glass covers in a preliminary cleansing bath 846. The preliminary cleansing bath 846 can comprise 4% by weight HF and 4% by weight H₂SO₄. The duration for the preliminary cleansing bath 846 can be from approximately thirty (30) seconds to approximately ten (10) minutes.

The process 840 may continue with preheating 848 the glass covers slowly, so as to limit thermal shock to the glass covers in a subsequent step of chemically strengthening 850 the glass covers. The glass covers may be chemically strengthened using an Alkali metal ion bath (e.g., potassium bath). Preheating can occur over a period of time, e.g., as long as approximately thirty (30) minutes, to bring temperature of the glass covers up from approximately room temperature to approximately three-hundred-and-fifty (350) degrees Celsius.

The process 840 may continue by cleansing the glass covers in an intermediate cleansing bath 852. Here, optionally, the glass cover can be briefly submerged in the intermediate cleansing bath 852. The intermediate cleansing bath 846 can comprise suitably heated water. The process 840 may continue with chemically toughening 854 the glass covers. For example, the glass cover can be chemically toughened 854 by submerging such in a sodium bath. The sodium bath can allow back ion exchange of sodium ions for Alkali metal ions (e.g., potassium), thereby chemically toughening the glass covers.

The process 840 may continue with cool down 856 of the glass covers. The cool down 856 can be performed slowly in a cool down oven. Cool down can be over a duration as long as approximately one hour, to bring temperature of the glass covers down from approximately the temperature of the sodium bath for chemically toughening the glass covers to approximately one-hundred-and-fifty (150) degrees Celsius.

Once the glass covers are sufficiently cooled, the process 840 may continue with attaching 858 each of the glass covers to a corresponding consumer electronic product. Upon attaching 858 each of the glass covers to a corresponding consumer electronic product, the process 840 for strengthening and toughening the glass cover can end.

FIG. 8C illustrates an exemplary profile 880 according to one embodiment. The exemplary profile 880 represents compressive stress at an outer region of a piece of glass as a function of depth into the piece of glass from an outer surface. Generally speaking, the profile 880 achieved with one or more ion exchange processes, where a peak compressive stress (Smax) is not at the surface of the piece of glass. Instead, the peak compressive stress (Smax) is controlled to be provided sub-surface of the outer surface of the glass. In one embodiment, the peak compressive stress (Smax) can be two-hundred (200) to two-thousand (2000) MPa, a depth (D1) of the peak compressive stress (Smax) in from the outer surface of the glass is five (5) to fifty (50) microns, and a depth (D2) of the compressive stress region into the glass from the outer surface can be twenty (20) to two-hundred (200) microns.

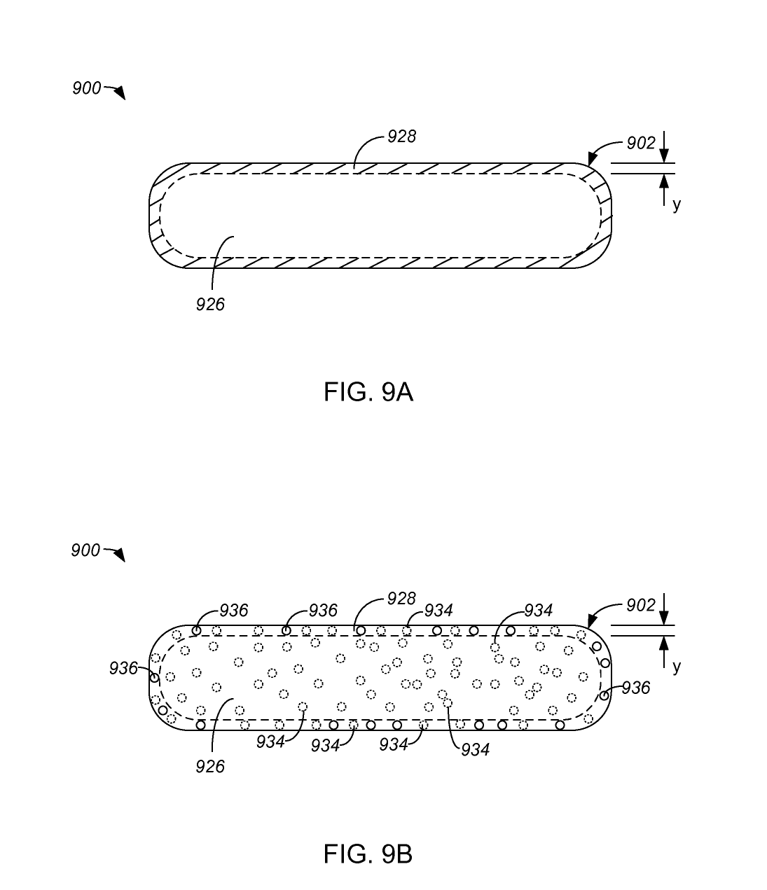

A glass cover which has undergone a chemical strengthening process generally includes a chemically strengthened layer, as previously mentioned. FIGS. 9A and 9B are cross-sectional diagrams of a glass cover which has been chemically treated such that a chemically strengthened layer is created according to one embodiment. A glass cover 900 includes a chemically strengthened layer 928 and a non-chemically strengthened portion 926. Although the glass cover 900 is, in one embodiment, subjected to chemical strengthening as a whole, the outer surfaces receive the strengthening. The effect of the strengthening is that the non-chemically strengthened portion 926 is in tension, while the chemically strengthened layer 928 is in compression. While glass cover 900 is shown as having a rounded edge geometry 902, it should be appreciated that glass cover 900 may generally have any edge geometry such as those selected to increase the strength of the edges of glass cover 900. Rounded edge geometry 902 is depicted by way of example, and not for purposes of limitation.

Chemically strengthened layer 928 has a thickness (y) which may vary depending upon the requirements of a particular system in which glass cover 900 is to be utilized. Non-chemically strengthened portion 926 generally includes Na⁺ ions 934 but no Alkali metal ions 936. A chemical strengthening process causes chemically strengthened layer 928 to be formed such that chemically strengthened layer 928 includes both Na⁺ ions 934 and Alkali metal ions 936. In one embodiment, as illustrated in FIG. 9B, chemically strengthened layer 928 may be such that an outer portion of chemically strengthened layer 928 includes substantially more Na⁺ ions 934 than an underlying portion of chemically strengthened layer 928 which includes both Na⁺ ions 934 and Alkali metal ions 936.

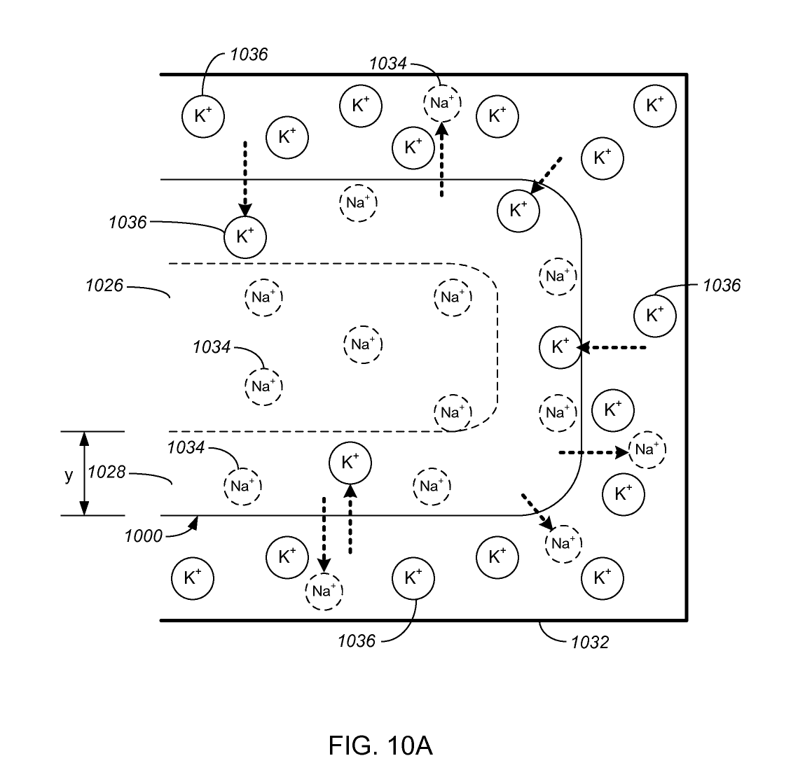

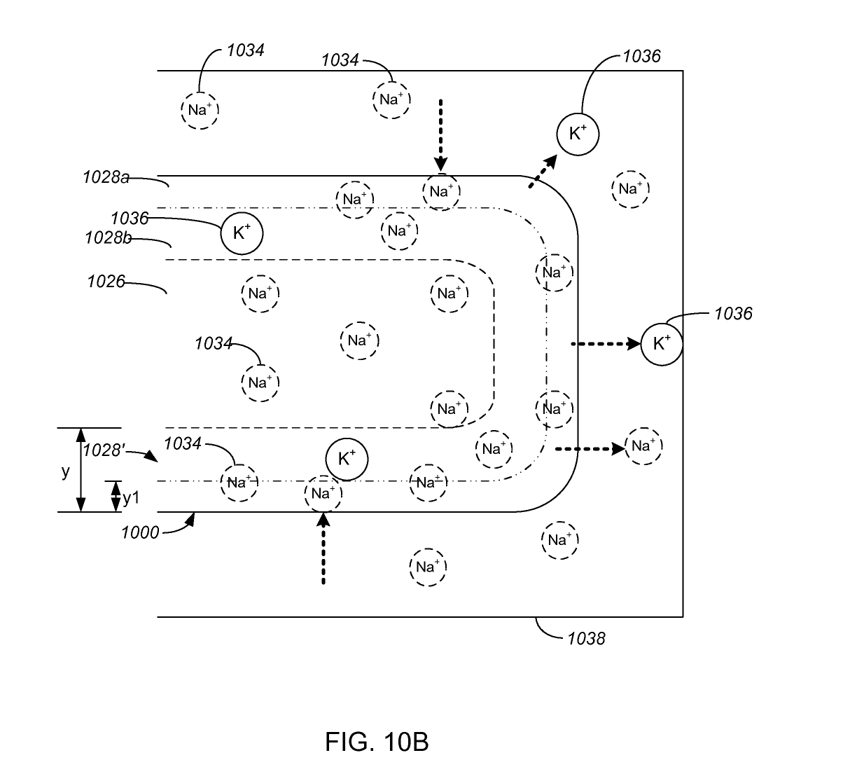

FIG. 10A is a diagrammatic representation of a chemical treatment process that involves submerging a glass cover in an ion bath according to one embodiment. When glass cover 1000, which is partially shown in cross-section, is submerged or soaked in a heated ion bath 1032, diffusion occurs. As shown, Alkali metal ions 1034 which are present in glass cover 1000 diffuse into ion bath 1032 while Alkali metal ions 1036 (e.g., potassium (K⁺)) in ion bath 1032 diffuse into glass cover 1000, such that a chemically strengthened layer 1028 is formed. In other words, Alkali metal ions 1036 from ion bath 1032 can be exchanged with Na⁺ ions 1034 to form chemically strengthened layer 1028. Alkali metal ions 1036 typically would not diffuse into a center portion 1026 of glass cover 1000. By controlling the duration (i.e., time) of a chemical strengthening treatment, temperature and/or the concentration of Alkali metal ions 1036 in ion bath 1032, the thickness (y), or depth of layer, of chemically strengthened layer 1028 may be substantially controlled.

As discussed above, in one embodiment, glass cover 1000 may further be treated to substantially remove Alkali metal ions (e.g., K⁺ ions) 1036 located near an outer surface of chemically strengthened layer 1028. A sodium bath may be used to facilitate the removal of such Alkali metal ions (e.g., K⁺ ions) 1036. FIG. 10B is a diagrammatic representation of a chemical treatment process that involves submerging a glass cover in a sodium bath after the glass cover has previously been submerged in a Alkali metal bath according to one embodiment. Glass cover 1000, which was previously submerged in an heated ion bath (e.g., potassium bath) as described above with respect to FIG. 10A, may be submerged in a sodium bath 1038 such that a chemically strengthened layer 1028′ may include an outer layer 1028a which includes little or no Alkali metal ions 1036 and substantially only Na⁺ ions 1034, and an inner layer 1028b which includes both Na⁺ ions 1034 and Alkali metal ions (e.g., K⁺ ions) 1036. When glass cover 1000 is submerged in sodium bath 1038, Na⁺ ions 1034 can displace Alkali metal ions (e.g., K⁺ ions) 1036 from outer layer 1028a, while Alkali metal ions (e.g., K⁺ ions) 1036 remain in inner layer 1028b. Thus, inner layer 1028b, which includes Alkali metal ions (e.g., K⁺ ions) 1036 and Na⁺ ions 1034, is effectively positioned between outer layer 1028a and a non-chemically strengthened portion 1026. The non-chemically strengthened portion 1026 typically has no Alkali metal ions (e.g., K⁺ ions) 1036, and the outer layer 1028a has reduced levels of Alkali metal ions (e.g., K⁺ ions) 1036 as compared to the inner layer 1028b. It may be that the outer layer 1028a has little or none of the Alkali metal ions (e.g., K⁺ ions) 1036. Displaced Alkali metal ions (e.g., K⁺ ions) 1036 may effectively diffuse from outer layer 1028b into sodium bath 1038.

Chemically strengthened layer 1028′ may have a thickness (y), while outer layer 1028a may have a thickness (y1). The thickness (y1) may be substantially controlled by the concentration of Na⁺ ions 1034 in sodium bath 1038, as well as by the amount of time glass cover 1000 is submerged in sodium bath 1038.

The concentration of Alkali metal ions (e.g., K⁺ ions) in a heated ion bath (e.g., potassium bath) may be varied while a glass cover is soaking in the heated ion bath. In other words, the concentration of Alkali metal ions (e.g., K⁺ ions) in a potassium bath may be maintained substantially constant, may be increased, and/or may be decreased while a glass cover is submerged in the heated ion bath. For example, as Alkali metal ions displace Na⁺ ions in the glass, the Na⁺ ions become part of the heated ion bath. Hence, the concentration of Alkali metal ions in the heated ion bath may change unless additional Alkali metal ions are added into the heated ion bath.

Varying the concentration of K⁺ ions in a potassium bath and/or varying the soaking time of a glass cover in the potassium bath may enable the tension at approximately the center of the glass cover to be controlled. In one embodiment, a glass cover can be placed in a heated ion bath for approximately 10-15 hours, where the heated ion bath is, for example, a potassium bath with a K⁺ ion concentration that is between approximately forty percent (40%) and approximately ninety-eight percent (98%). A K⁺ ion concentration that is substantially greater than approximately ninety percent (90%) to approximately ninety-five percent (95%) may be used in one embodiment.

The parameters associated with an Alkali metal bath and/or a sodium bath may generally vary widely. The concentration of Alkali metal (e.g., potassium) in an Alkali metal bath may vary, as previously mentioned. Similarly, the concentration of sodium in a sodium bath used in a double exchange process may also vary. A suitable Na+ ion concentration for the sodium bath may be provided by a molecular ratio of approximately fifty percent (50%) to ninety percent (90%) KNO₃, with the remainder (fifty percent 50% to ten percent 10%) NaNO3. For example, in one embodiment, a suitable Na⁺ ion concentration for the sodium bath may be provided by an approximate molecular ratio of KNO₃ seventy percent (70%) and NaNO₃ thirty percent (30%.) Additionally, the temperature to which the baths are heated, as well as the length of time glass covers are submerged in the baths may also vary widely. The temperature is not limited to being between approximately 370 degrees Celsius and approximately 430 degrees Celsius. By way of example, a total time a glass cover is submerged in an Alkali metal bath may be approximately ten (10) hours. Further, a total time a glass cover is submerged in an Alkali metal bath and a sodium bath during a double exchange process may be approximately ten hours (10), e.g., where the glass cover is submerged in the Alkali metal bath for approximately 6.7 hours and in the sodium bath for approximately 3.3 hours. The length of time being submerged (e.g., soaked) in either of the baths can vary depending on the concentrations. The length of time in the sodium bath depends upon Na⁺ ion concentration, wherein less time in the sodium bath is preferred for higher Na⁺ ion concentration. For example, with the sodium bath having a relatively higher Na⁺ ion concentration provided by the approximate molecular ratio of KNO₃ seventy percent (70%) and NaNO₃ thirty percent (30%), less than approximately one half hour in the sodium bath may be suitable. In other examples, shorter or longer times in the sodium bath may be employed, such as approximately one (1) hour, ten (10) minutes or approximately one (1) minute.

The concentration of Alkali metal ions in an ion bath may be varied while a glass cover is soaking in the ion bath. In other words, the concentration of Alkali metal ions in an ion bath may be maintained substantially constant, may be increased, and/or may be decreased while a glass cover is submerged in the ion bath without departing from the spirit or the scope of the present invention. For example, as Alkali metal ions displace Na⁺ ions in the glass, the Na⁺ ions become part of the ion bath. Hence, the concentration of Alkali metal ions in the ion bath may change unless additional Alkali metal ions are added into the ion bath.

The techniques describe herein may be applied to a variety of electronic devices including but not limited handheld electronic devices, portable electronic devices and substantially stationary electronic devices. Examples of these include any known consumer electronic device that includes a display. By way of example, and not by way of limitation, the electronic device may correspond to media players, mobile phones (e.g., cellular phones), PDAs, remote controls, notebooks, tablet PCs, monitors, all in one computers and the like.

Although only a few embodiments of the present invention have been described, it should be understood that the present invention may be embodied in many other specific forms without departing from the spirit or the scope of the present invention. By way of example, the steps associated with the methods of the present invention may vary widely. Steps may be added, removed, altered, combined, and reordered without departing from the spirit of the scope of the present invention.

This application also references: (i) U.S. patent application Ser. No. 12/193,001, filed Aug. 16, 2008, entitled “METHODS AND SYSTEMS FOR STRENGTHENING LCD MODULES,” which is herein incorporated by reference; (ii) U.S. patent application Ser. No. 12/172,073, filed Jul. 11, 2008, entitled “METHODS AND SYSTEMS FOR INTEGRALLY TRAPPING A GLASS INSERT IN A METAL BEZEL,” which is herein incorporated by reference; (iii) U.S. Provisional Patent Application No. 61/156,803, filed Mar. 2, 2009 and entitled “Techniques for Strengthening Glass Covers for Portable Electronic Devices,” which is herein incorporated by reference; (iv) U.S. Provisional Patent Application No. 61/247,493, filed Sep. 30, 2009 and entitled “Techniques for Strengthening Glass Covers for Portable Electronic Devices,” which are herein incorporated by reference; (v) U.S. patent application Ser. No. 12/895,372, filed Sep. 30, 2010 and entitled “Techniques for Strengthening Glass Covers for Portable Electronic Devices,” which are herein incorporated by reference; and (vi) U.S. patent application Ser. No. 12/895,393, filed Sep. 30, 2010 and entitled “Techniques for Strengthening Glass Covers for Portable Electronic Devices,” which are herein incorporated by reference.

The various aspects, features, embodiments or implementations of the invention described above can be used alone or in various combinations.

While this specification contains many specifics, these should not be construed as limitations on the scope of the disclosure or of what may be claimed, but rather as descriptions of features specific to particular embodiment of the disclosure. Certain features that are described in the context of separate embodiments can also be implemented in combination. Conversely, various features that are described in the context of a single embodiment can also be implemented in multiple embodiments separately or in any suitable subcombination. Moreover, although features may be described above as acting in certain combinations, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results.

While this invention has been described in terms of several embodiments, there are alterations, permutations, and equivalents, which fall within the scope of this invention. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. A method for producing a glass cover for an exposed surface of a consumer electronic product, the method comprising:
obtaining a glass sheet;
singulating the glass sheet into a plurality of glass covers, each of the glass covers being suitably sized to be provided on the exposed surface of a consumer electronic product;
chemically strengthening the glass covers; and
chemically toughening the glass covers.

2. A method as recited in claim 1,
wherein the chemically strengthening of the glass covers produces an enhanced strength of the glass covers, and
wherein the chemically toughening of the glass covers produces a limited reduction in the enhanced strength of the glass covers.

3. A method as recited in claim 2, wherein the chemically toughening of the glass covers comprises:
a chemical toughening treatment over a period of time; and
limiting the period of time of the chemical toughening treatment, so as to produce the limited reduction in the enhanced strength of the glass covers.

4. A method as recited in claim 1,
wherein the chemically strengthening of the glass covers produces an initial compressive surface stress of the glass covers, and
wherein the chemically toughening of the glass covers reduces the initial compressive surface stress of the glass covers to a reduced compressive surface stress.

5. A method as recited in claim 1,
wherein the chemically strengthening of the glass covers produces an initial compressive surface stress of the glass covers, and
wherein the chemically toughening of the glass covers reduces the initial compressive surface stress of the glass covers to a reduced compressive surface stress having an increasing stress profile extending inwardly from surfaces of each of the glass covers.

6. A method as recited in claim 1,
wherein the chemically strengthening of the glass covers produces an initial compressive surface stress of the glass covers, and
wherein the chemically toughening of the glass covers limits reduction of the initial compressive surface stress relative to a predetermined compressive limit, so as to produce a reduced compressive surface stress that remains substantially greater than the predetermined compressive limit.

7. A method as recited in claim 1,
wherein the chemically strengthening of the glass covers produces an initial central tension in the glass covers, and
wherein the chemically toughening the glass covers reduces the initial central tension in the glass covers to a reduced central tension.

8. A method as recited in claim 1,
wherein the chemically strengthening of the glass covers produces an initial central tension in the glass covers, and
wherein the chemically toughening of the glass covers reduces the initial central tension relative to a predetermined tension limit, so as to produce a reduced central tension that is substantially less than the predetermined tension limit.

9. A method as recited in claim 1, wherein the method further comprises:
chemically pre-treating the glass covers in a preliminary cleansing bath prior to chemically strengthening the glass covers.

10. A method as recited in claim 1, wherein the method further comprises:
preheating the glass covers prior to chemically strengthening the glass covers, so as to limit thermal shock to the glass covers in chemically strengthening the glass covers.

11. A method as recited in claim 1, wherein the method further comprises:
cleansing the glass covers in an intermediate cleansing bath after chemically strengthening the glass covers, and prior to chemically toughening the glass covers.

12. A method as recited in claim 1, wherein the method further comprises:
thereafter cooling down the glass covers in a cool down oven.

13. A method as recited in claim 1, wherein the method further comprises:
thereafter attaching each of the glass covers to a corresponding consumer electronic product.

14. A consumer electronic product, comprising:
a housing having a front surface, a back surface and side surfaces;
electrical components provided at least partially internal to the housing, the electrical components including at least a controller, a memory, and a display, the display being provided at or adjacent the front surface of the housing; and
a glass cover provided at or over the front surface of the housing such that it is provided over the display, wherein the glass cover is a chemically strengthened and chemically toughened glass cover.

15. A consumer electronic product as recited in claim 14, wherein the chemically strengthened and chemically toughened glass cover is characterized by an increasing compressive stress profile extending inwardly from surfaces of the chemically strengthened and chemically toughened glass cover.

16. A consumer electronic product as recited in claim 14, wherein the chemically strengthened and chemically toughened glass cover is characterized by a compressive stress profile having a submerged peak below the surface of the chemically strengthened and chemically toughened glass cover.

17. A consumer electronic product as recited in claim 14,
wherein the chemically strengthened and chemically toughened glass cover is characterized by a compressive stress profile having a submerged peak at a depth below the surfaces of the chemically strengthened and chemically toughened glass cover, and
wherein the depth of the submerged profile peak is substantially within a range of approximately ten (10) to thirty (30) microns.

18. A consumer electronic product as recited in claim 14, wherein the chemically strengthened and chemically toughened glass cover comprises alumino-silicate glass.

19. A consumer electronic product as recited in claim 14, wherein the consumer electronic product is a handheld electronic device.

20. A consumer electronic product as recited in claim 14, wherein the consumer electronic product is a cell phone, a portable media player, a personal digital assistant, or a remote control device.

21. A consumer electronic product as recited in claim 14, wherein the thickness of the glass cover is less than 1 mm.

22. A glass cover member suitable for attachment to a housing for a handheld electronic device, the glass cover member being produced, strengthened and toughened by the process of:
obtaining a glass sheet;
singulating the glass sheet into a plurality of glass cover members, each of the glass cover members being suitably sized to be provided on an exposed surface of the handheld electronic device, each of the glass cover members including at least one outer surface;
chemically strengthening the at least one outer surface of each of the glass cover members, wherein chemically strengthening the at least one outer surface of each of the glass cover members includes altering a composition of the at least one outer surface of each of the glass cover members; and
toughening the glass cover members by reducing compressive stress at the surface of the outer surfaces of the glass cover members such that a peak compressive stress is inwards from the surface of the outer surfaces.

23. A glass cover member as recited in claim 22, wherein toughening the glass cover members comprises chemically toughening the glass cover members.

24. A consumer electronic product, comprising:
a housing having a front surface, a back surface and side surfaces;
electrical components provided at least partially internal to the housing; and
a glass member that has been chemically strengthened such that a peak compressive stress for the glass member is sub-surface of an exposed surface of the glass member.

25. A consumer electronic product as recited in claim 24, wherein the glass member is attached adjacent to the housing.

26. A consumer electronic product as recited in claim 24, wherein the glass member forms a substantial portion of the front surface or the back surface of the housing.

27. A consumer electronic product as recited in claim 24, wherein the peak compressive stress (Smax) is at a depth of five (5) to fifty (50) microns inward from the outer surface of the glass member.

28. A consumer electronic product as recited in claim 24, wherein the glass member has a thickness of 0.5 to 2.0 mm, and wherein the peak compressive stress (Smax) is approximately two-hundred (200) to two-thousand (2000) MPa.

29. A consumer electronic product as recited in claim 24, wherein compressive stress for the glass member extends into the glass from the outer surface a depth of twenty (20) to two-hundred (200) microns.

30. A consumer electronic product as recited in claim 24, wherein compressive stress for the glass member has profile that include a first region with an increasing stress profile extending inwardly from the outer surface of the glass member to a first depth, and a second region with a decreasing stress profile extending inwardly from the first depth to a second depth.
